(19) United States
(12) Patent Application Publication
(10) Pub. No.: US 2011/0015078 A1
(43) Pub. Date: Jan. 20, 2011

(54) CRYOGENICALLY COOLED SUPERCONDUCTOR RF HEAD COIL ARRAY AND HEAD-ONLY MAGNETIC RESONANCE IMAGING (MRI) SYSTEM USING SAME

(76) Inventors: Erzhen Gao, Milburn, NJ (US); Qiyuan Ma, Milburn, NJ (US)

Correspondence Address: FROMMER LAWRENCE & HAUG, 745 FIFTH AVENUE- 10TH FL., NEW YORK, NY, 10151, US

(21) Appl. No.: 12/764,036

(22) Filed: Apr. 20, 2010

Related U.S. Application Data
(60) Provisional application No. 61/171,074, filed on Apr. 20, 2009.

(51) Int. Cl. G01R 33/3815

(52) U.S. Cl. 505/162; 324/318

(57) ABSTRACT

A superconducting main magnet system for a head-dedicated MRI system is provided, and a head-only MRI system may comprise such a superconducting main magnet and a cryogenically-cooled superconducting RF head-coil array. The superconducting main magnet may comprise a first and second set of high temperature superconductor coils which are configured to be coaxial relative to a common longitudinal axis. The first coil set includes at least two coils having an inner radius and disposed in a first region of a length along the common axis to cover a head and neck of a human body, and the second coil set includes at least one coil having an inner radius and disposed in a second region of a length along the common axis to cover a portion of a human torso, wherein the inner radius of the second coil set is greater than the inner radius of the first coil set. The first and second coils are configured to provide a uniform magnetic field in the first region to provide for imaging a region of interest of the individual's head when positioned within the first region.

### RELATED APPLICATIONS

This application claims the benefit of U.S. Provisional Application No. 61/171,074, filed Apr. 20, 2009, which is incorporated herein by reference in its entirety.

### TECHNICAL FIELD

The present invention relates generally to magnetic resonance imaging and spectroscopy, and, more particularly, to magnetic resonance imaging and spectroscopy apparatus employing superconductor components, and to methods for manufacturing such apparatus.

### BACKGROUND

Magnetic Resonance Imaging (MRI) technology is commonly used today in larger medical institutions worldwide, and has led to significant and unique benefits in the practice of medicine. While MRI has been developed as a well-established diagnostic tool for imaging structure and anatomy, it has also been developed for imaging functional activities and other biophysical and biochemical characteristics or processes (e.g., blood flow, metabolites/metabolism, diffusion), some of these magnetic resonance (MR) imaging techniques being known as functional MRI, spectroscopic MRI or Magnetic Resonance Spectroscopic Imaging (MRSI), diffusion weighted imaging (DWI), and diffusion tensor imaging (DTI). These magnetic resonance imaging techniques have broad clinical and research applications in addition to their medical diagnostic value for identifying and assessing pathology and determining the state of health of the tissue examined.

During a typical MRI examination, a patient's body (or a sample object) is placed within the examination region and is supported by a patient support in an MRI scanner where a substantially constant and uniform primary (main) magnetic field is provided by a primary (main) magnet. The magnetic field aligns the nuclear magnetization of precessing atoms such as hydrogen (protons) in the body. A gradient coil assembly within the magnet creates a small variation of the magnetic field in a given location, thus providing resonance frequency encoding in the imaging region. A radio frequency (RF) coil is selectively driven under computer control according to a pulse sequence to generate in the patient a temporary oscillating transverse magnetization signal that is detected by the RF coil and that, by computer processing, may be mapped to spatially localized regions of the patient, thus providing an image of the region-of-interest under examination.

In a common MRI configuration, the static main magnetic field is typically produced by a solenoid magnet apparatus, and a patient platform is disposed in the cylindrical space bounded by the solenoid windings (i.e. the main magnet bore). The windings of the main field are typically implemented as a low temperature superconductor (LTS) material, and are super-cooled with liquid helium in order to reduce resistance, and, therefore, to minimize the amount of heat generated and the amount of power necessary to create and maintain the main field. The majority of existing LTS superconducting MRI magnets are made of a niobium-titanium (NbTi) and/or Nb₃Sn material which is cooled with a cryostat to a temperature of 4.2 K.

As is known to those skilled in the art, the magnetic field gradient coils generally are configured to selectively provide linear magnetic field gradients along each of three principal Cartesian axes in space (one of these axes being the direction of the main magnetic field), so that the magnitude of the magnetic field varies with location inside the examination region, and characteristics of the magnetic resonance signals from different locations within the region of interest, such as the frequency and phase of the signals, are encoded according to position within the region (thus providing for spatial localization). Typically, the gradient fields are created by current passing through coiled saddle or solenoid windings, which are affixed to cylinders concentric with and fitted within a larger cylinder containing the windings of the main magnetic field. Unlike the main magnetic field, the coils used to create the gradient fields typically are common room temperature copper windings. The gradient strength and field linearity are of fundamental importance both to the accuracy of the details of the image produced and to the information on tissue chemistry (e.g., in MRSI).

Since MRI's inception, there has been a relentless pursuit for improving MRI quality and capabilities, such as by providing higher spatial resolution, higher spectral resolution (e.g., for MRSI), higher contrast, and faster acquisition speed. For example, increased imaging (acquisition) speed is desired to minimize imaging blurring caused by temporal variations in the imaged region during image acquisition, such as variations due to patient movement, natural anatomical and/or functional movements (e.g., heart beat, respiration, blood flow), and/or natural biochemical variations (e.g., caused by metabolism during MRSI). Similarly, for example, because in spectroscopic MRI the pulse sequence for acquiring data encodes spectral information in addition to spatial information, minimizing the time required for acquiring sufficient spectral and spatial information to provide desired spectral resolution and spatial localization is particularly important for improving the clinical practicality and utility of spectroscopic MRI.

Several factors contribute to better MRI image quality in terms of high contrast, resolution, and acquisition speed. An important parameter impacting image quality and acquisition speed is the signal-to-noise ratio (SNR). Increasing SNR by increasing the signal before the preamplifier of the MRI system is important in terms of increasing the quality of the image. One way to improve SNR is to increase the magnetic field strength of the magnet as the SNR is proportional to the magnitude of the magnetic field. In clinical applications, however, MRI has a ceiling on the field strength of the magnet (the US FDA's current ceiling is 3 T (Tesla)). Other ways of improving the SNR involve, where possible, reducing sample noise by reducing the field-of-view (where possible), decreasing the distance between the sample and the RF coils, and/or reducing RF coil noise.

Despite the relentless efforts and many advancements for improving MRI, there is nevertheless a continuing need for yet further improvements in MRI, such as for providing greater contrast, improved SNR, higher acquisition speeds, higher spatial and temporal resolution, and/or higher spectral resolution.

Additionally, a significant factor affecting further use of MRI technology is the high cost associated with high magnetic field systems, both for purchase and maintenance. Thus, it would be advantageous to provide a high quality MRI imaging system that is capable of being manufactured and/or maintained at reasonable cost, permitting MRI technology to be more widely used.

### SUMMARY OF INVENTION

Various embodiments of the present invention provide a cryogenically cooled superconducting RF head-coil array which may be used in whole-body MRI scanners and/or in dedicated, head-only MRI systems (also referred to herein as “head-dedicated MRI systems,” “head-only MRI systems,” or the like). Some embodiments of the invention provide a head-dedicated MRI system and, more particularly, various embodiments provide a superconducting main magnet for a head-dedicated MRI system which, in some embodiments, further comprises a cryogenically-cooled superconducting RF head-coil array according to embodiments of the present invention.

In accordance with some embodiments, a system for head magnetic resonance imaging, comprises: a first and second set of high temperature superconductor coils which are configured to be coaxial relative to a common longitudinal axis; wherein the first coil set includes at least two coils having an inner radius and disposed in a first region of a length along the common axis to cover a head and neck of a human body, and the second coil set includes at least one coil having an inner radius and disposed in a second region of a length along the common axis to cover a portion of a human torso; and wherein the first and second coils are configured to provide a uniform magnetic field in the first region to provide for imaging a region of interest of the individual's head when positioned within the first region.

The longitudinal position and extension, the number of turns, and electric current direction of each coil may be designed, according to some embodiments, to provide a 1-10 ppm uniform magnetic field within the first region for head imaging. The first set of coils may have an inner radius in a range of 25-35 cm and disposed in a first region of a length along the common axis in a range of 40-60 cm, and the second set of coils may have an inner radius in a range of 30-40 cm and disposed in a second region of a length along the common axis in a range of 15-25 cm to cover a portion of a human torso, which portion may comprise the shoulders.

In accordance with some embodiments, at least one coil may be wound to carry current in the reverse direction relative to the rest of coils. The system may further comprise a shielding coil which surrounds said common longitudinal axis and is coaxial with said first and second coils, and which may extend over the length of the first and second regions.

The system for head magnetic resonance imaging may also comprise a superconductor radiofrequency head coil array module disposed coaxially with respect to said common longitudinal axis and configured to at least receive radiofrequency signals generated within said first region in which the individual's head is positioned for imaging. Such a radiofrequency head coil array may comprise a plurality of high temperature superconductor coils disposed azimuthally about the common longitudinal axis.

It will be appreciated by those skilled in the art that the foregoing brief description and the following detailed description are exemplary and explanatory of the present invention, but are not intended to be restrictive thereof or limiting of the advantages which can be achieved by this invention. Additionally, it is understood that the foregoing summary of the invention is representative of some embodiments of the invention, and is neither representative nor inclusive of all subject matter and embodiments within the scope of the present invention. Thus, the accompanying drawings, referred to herein and constituting a part hereof, illustrate embodiments of this invention, and, together with the detailed description, serve to explain principles of embodiments of the invention. Aspects, features, and advantages of embodiments of the invention, both as to structure and operation, will be understood and will become more readily apparent when the invention is considered in the light of the following description made in conjunction with the accompanying drawings, in which like reference numerals designate the same or similar parts throughout the various figures.

### BRIEF DESCRIPTION OF THE DRAWINGS

Aspects, features, and advantages of embodiments of the invention, both as to structure and operation, will be understood and will become more readily apparent when the invention is considered in the light of the following description made in conjunction with the accompanying drawings, in which like reference numerals designate the same or similar parts throughout the various figures, and wherein:

FIGS. 1A and 1B schematically depict orthogonal views of an illustrative cryogenically cooled superconducting RF head coil array, in accordance with some embodiments of the present invention;

FIG. 2 schematically illustrates wall(s) of the vacuum chamber depicted in FIG. 1A being implemented as a double-walled glass Dewar, in accordance with some embodiments of the present invention;

FIG. 3 schematically depicts an illustrative cross-sectional view along the longitudinal axis of a superconductor RF head coil array corresponding to embodiments depicted in FIGS. 1A and 1B with the vacuum chamber comprising a Dewar 1 according to various embodiments represented by FIG. 2, in accordance with some embodiments of the present invention;

FIGS. 4A and 4B, depict an illustrative alternative implementation of a superconductor RF head coil array (module), in accordance with some embodiments of the present invention;

FIG. 5 schematically depicts a cross section of an illustrative MRI system, in accordance with some embodiments of the present invention;

FIG. 6 schematically depicts an illustrative RF head coil array that includes thermal radiation screening, in accordance with some embodiments of the present invention;

FIG. 7 schematically depicts a cross-sectional view of a superconducting main magnet of a head-only MRI system, in accordance with some embodiments of the present invention;

FIG. 8 depicts with reference to the z-r plane a coil configuration of a superconducting main magnet system, in accordance with some embodiments of the present invention;

FIG. 9 depicts a normalized current distribution for the main magnet coil arrangement corresponding to the illustrative embodiment of FIGS. 7 and 8, in accordance with some embodiments of the present invention;

FIG. 10 is an illustrative coil pattern (depicted in the z-r plane, with units normalized to meters) of a 3 T head magnetic resonance imaging scanner, in accordance with various embodiments of the present invention;

FIG. 11 is a plot showing the magnetic field distribution for the illustrative embodiment depicted in FIG. 10, in accordance with some embodiments of the present invention; and

FIG. 12 shows the fringe fields of one Gauss (1 G), three Gauss (3 G) and five Gauss (5 G) lines for the field distribution of FIG. 11, in accordance with an illustrative embodiment of the present invention.

### DESCRIPTION OF EMBODIMENTS OF THE INVENTION

The ensuing description discloses (i) various embodiments of a cryogenically cooled superconducting RF head-coil array which may be used in whole-body MRI scanners and/or in dedicated, head-only MRI systems (also referred to herein as “head-dedicated MRI systems,” “head-only MRI systems,” or the like) and (ii) various embodiments of a head-dedicated MRI system and, more particularly, various embodiments of a superconducting main magnet for a head-dedicated MRI system which, in some embodiments, further comprises a cryogenically-cooled superconducting RF head-coil array according to embodiments of the present invention.

More specifically, as will be further understood by those skilled in the art in view of the ensuing description, a cryogenically-cooled superconducting RF head-coil array coil according to various embodiments of the present invention may be implemented in myriad magnetic resonance imaging and spectroscopy systems, such as systems employing conventional copper gradient coils, systems employing superconducting gradient coils (e.g., such as disclosed in U.S. patent application Ser. No. 12/416,606, filed Apr. 1, 2009, and in Provisional Application No. 61/170,135, filed Apr. 17, 2009, each of which is hereby incorporated by reference in its entirety), whole body systems, dedicated head-only systems, systems with a vertically or horizontally oriented main magnetic field, open or closed systems, etc. Similarly, as will be further understood by those skilled in the art in view of the ensuing description, a head-dedicated MRI system employing a superconducting main magnet according to various embodiments of the present invention may be implemented in myriad magnetic resonance imaging and spectroscopy systems, such as systems employing conventional copper gradient coils, systems employing superconducting gradient coils (e.g., such as disclosed in U.S. patent application Ser. No. 12/416,606, filed Apr. 1, 2009, and in Provisional Application No. 61/170,135, filed Apr. 17, 2009, each of which is hereby incorporated by reference in its entirety), systems employing conventional (e.g., copper) head coils or coil arrays, and/or systems employing a superconducting RF head coil array (e.g., according to superconducting RF head-coil embodiments described herein), etc. Similarly, it will also be understood by those skilled in the art that while various portions of the ensuing description may be set forth in the context of an MRI system that may be used for structural examination of a patient, various embodiments of the present invention may be employed in connection with magnetic resonance (MR) systems operated and/or configured for other modalities, such as functional MRI, diffusion weighted and/or diffusion tensor MRI, MR spectroscopy and/or spectroscopic imaging, etc. Additionally, as used herein, MRI includes and embraces magnetic resonance spectroscopic imaging, diffusion tensor imaging (DTI), as well as any other imaging modality based on nuclear magnetic resonance.

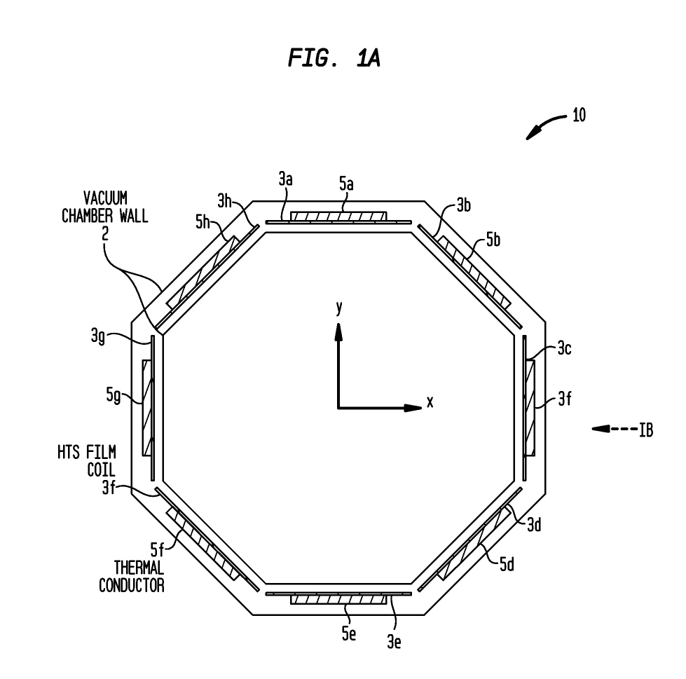

FIGS. 1A and 1B schematically depict orthogonal views of an illustrative cryogenically cooled superconducting RF head coil array 10, in accordance with some embodiments of the present invention. (For convenience and ease of reference and additional clarity of exposition, orthogonal x, y, z coordinates are depicted as a reference frame.) More specifically, FIG. 1A is a cross-sectional view in the x-y plane indicated by reference IA-IA′ in FIG. 1B, and illustrates a configuration of eight superconducting RF coils 3a-3h (also referred to herein collectively as superconductor RF coils 3 or RF coil array 3) each disposed in thermal contact with a respective one of eight thermal conductors 5a-5h (e.g., non-metallic high thermal conductivity materials, such as high thermal conductivity ceramic, such as sapphire or alumina), with the RF coils 3a-3h and thermal conductors 5a-5h being disposed within a sealed vacuum chamber having vacuum chamber wall(s) 2.

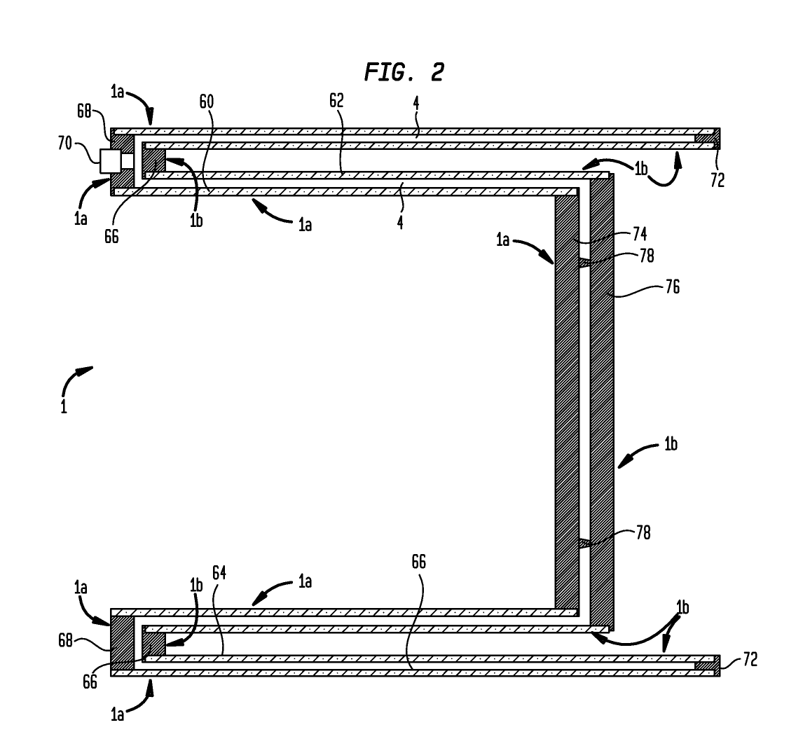

FIG. 1B is a side view along the longitudinal axis (i.e., z axis) viewed from the direction indicated by reference IB in FIG. 1A, and illustrates components comprising the cooling system of superconducting RF head coil array 10, the cooling system including thermal conductor 15 (e.g., non-metallic high thermal conductivity materials, such as high thermal conductivity ceramic, such as sapphire or alumina) in thermal contact with each of thermal conductors 5a-5h, cold head 9 in thermal contact with thermal conductor (sink) 15, and cryocooler 7 configured for maintaining the cold head 9 at a desired cryogenic temperature. For clarity of exposition, however, FIG. 1B does not show (i) the vacuum chamber comprising vacuum chamber wall(s) 2, (ii) coils 3b and 3d, and (iii) thermal conductors 5b and 5d (as will be further understood from the ensuing description (e.g., in connection with FIG. 3), FIG. 1B also does not show a vacuum chamber portion into which cryocooler 7 is mounted).

Accordingly, in the configuration of the superconducting RF head coil array 10 depicted in FIGS. 1A and 1B, coils 3a-3h are in vacuum and cooled by the thermal conductors 5a-5b, which conduct heat away from the coils to the thermal conductor/sink 15, which is thermally coupled with a cryogenic cooler 7. As will be understood by those skilled in the art, in some embodiments (e.g., low main magnetic field implementations, such as less than 3 T, or less than 1.5 T, etc.) small amounts of metal, such as copper, may be used for thermal conductor/sink 15 and/or possibly thermal conductors 5a-5h. In some embodiments, thermal conductors 5a-5h may be integrally formed with thermal conductor/sink 15, whereas in some embodiments, one or more of thermal conductors 5a-5h are distinct members that are mechanically joined (e.g., using epoxy, etc.) to thermal conductor/sink 15 to provide a good thermal conduction therebetween. In various embodiments, the coils 3a-3h may be cooled to a temperature in the range of about 4 K to 100 K, and more particularly, to a temperature below the critical temperature of the superconducting material (e.g., in some embodiments, below the critical temperature of a high temperature superconductor (HTS) material used for the RF coils 3a-3h).

More particularly, in accordance with various embodiments of the present invention, each of RF coil elements 3a-3h is implemented as a high temperature superconductor (HTS), such as YBCO and/or BSCCO, etc. (e.g., using an HTS thin film or HTS tape), though a low temperature superconductor (LTS) may be used in various embodiments. For example, in some embodiments, each of RF coil elements 3a-3h is an HTS thin film spiral coil and/or an HTS thin film spiral-interdigitated coil on a substrate such as sapphire or lanthanum aluminate. The design and fabrication of such coils is further described in and/or may be further understood in view of, for example, Ma et al., “Superconducting RF Coils for Clinical MR Imaging at Low Field,” Academic Radiology, vol. 10, no. 9, September 2003, pp. 978-987; Gao et al., “Simulation of the Sensitivity of HTS Coil and Coil Array for Head Imaging,” ISMRM-2003, no. 1412; Fang et al., “Design of Superconducting MRI Surface Coil by Using Method of Moment,” IEEE Trans. on Applied Superconductivity, vol. 12, no. 2, pp. 1823-1827 (2002); and Miller et al., “Performance of a High Temperature Superconducting Probe for In Vivo Microscopy at 2.0 T,” Magnetic Resonance in Medicine, 41:72-79 (1999), each of which is incorporated by reference herein in its entirety. Accordingly, in some embodiments, superconducting RF head coil array 10 is implemented as an HTS thin film RF head coil array.

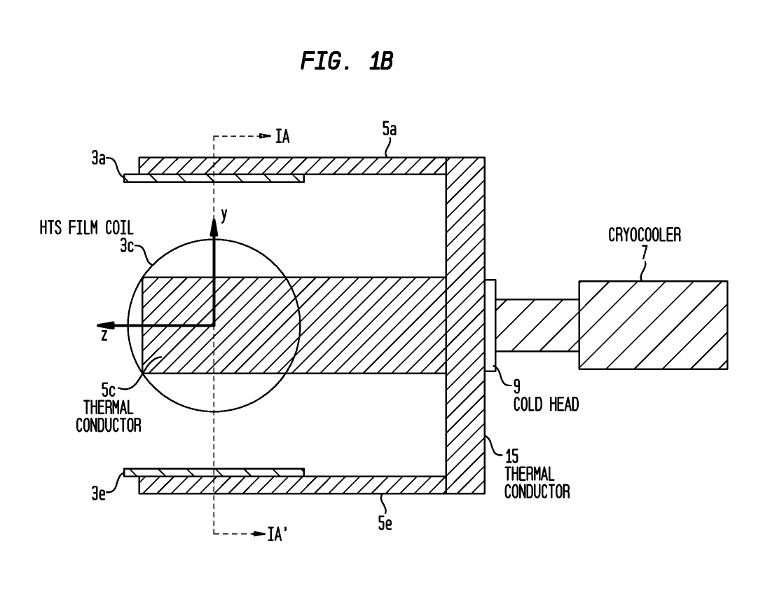

As depicted in FIG. 2, in accordance with some embodiments of the present invention, vacuum chamber comprising wall(s) 2 may comprise a double-walled Dewar 1 made of glass and/or other non-conductive, mechanically strong material(s), such as G10, RF4, plastic, and/or ceramic. More specifically, FIG. 2 schematically illustrates wall(s) 2 of the vacuum chamber depicted in FIG. 1A being implemented as a double-walled glass Dewar 1, in accordance with some embodiments of the present invention. It will be understood that the dimensions and shape of a cryogenically cooled superconducting RF head-coil array module may be modified according to various implementations of the present invention. In accordance with some implementations, FIG. 2 schematically illustrates a glass dewar portion 1 of a cryogenically cooled superconducting RF head-coil array module that may be used, for example, in a magnetic resonance imaging system dedicated to head imaging, wherein the glass dewar components may have the following approximate dimensions, provided merely by way of example and for additional clarity of exposition: cylinder 60 has an inner diameter, outer diameter, and axial length of 230 mm, 236 mm, and 254 mm, respectively; cylinder 62 has an inner diameter, outer diameter, and axial length of 246 mm, 252 mm, and 254 mm, respectively; cylinder 64 has an inner diameter, outer diameter, and axial length of 280 mm, 286 mm, and 312 mm, respectively; cylinder 66 has an inner diameter, outer diameter, and axial length of 296 mm, 302 mm, and 330 mm, respectively; inner bottom plate (circular/cylindrical) 74 has a diameter of 236 mm and a thickness of 12.7 mm; outer bottom plate (circular/cylindrical) 76 has a diameter of 252 mm and a thickness of 12.7 mm; ring (annular) 66 has an inner diameter, outer diameter, and thickness (axial) of 246 mm, 286 mm, and 12.7 mm, respectively; ring (annular) 68 has an inner diameter, outer diameter, and thickness (axial) of 230 mm, 302 mm, and 12.7 mm, respectively; and ring (annular) 72 has an inner diameter, outer diameter, and thickness (axial) of 280 mm, 302 mm, and 12.7 mm, respectively. Also shown are two of eight small spacer disks 78, having an approximate diameter of 5 mm as well as a height that provides for a gap of about 5 mm between the inner bottom plate 74 and outer bottom plate 76. In this illustrative embodiment, a plug 70 seals off a standard vacuum port in ring 68 through which the intra-dewar cavity is evacuated.

It will be understood that double-walled Dewar 1 may be constructed, in a variety of ways, as a continuous, hermetically sealed glass housing enclosing an interior chamber (or cavity) 4 in which at least a low vacuum condition and, in accordance with some embodiments, preferably at least a high vacuum condition (e.g., about 10⁻⁶ Torr or lower pressure) is maintained. For example, in accordance with some embodiments, double-walled Dewar 1 may be manufactured as follows: (i) forming two generally cylindrical (e.g., but hexagonal in cross-section transverse to the longitudinal/cylindrical access) double-walled structures each having a generally U-shaped wall cross-section, the first corresponding to continuous glass wall portion 1a (comprising cylinders 60 and 66, ring 68 and plate 74) and the second corresponding to continuous wall portion 1b (comprising cylinders 62 and 64, ring 66, and plate 76), (ii) fitting the generally cylindrical continuous glass wall portion 1b into the annular space of generally cylindrical continuous glass wall portion 1a, possibly using glass spacers therebetween (e.g., identified in FIG. 2 as disks 78), and (iii) glass-bonding, fusing, or otherwise sealing the open end between 1a and 1b (i.e., the end that is later sealably mounted to stainless steel chamber 8, further described below in connection with FIG. 3), (e.g., by bonding, fusing, or otherwise sealing ring 72 to the open end) to hermetically seal cavity 4 under high vacuum, and (iv) pumping the cavity 4 to a high vacuum through the depicted standard vacuum port, which is hermetically sealed (e.g., using cap 70) after pumping to the desired vacuum pressure. It may be appreciated that the vacuum sealing step may be performed in myriad ways. For example, portions 1a and 1b may be joined and sealed to each other within a vacuum chamber, or, as described, the ends of 1a and 1b may be fused to each other except for a small region that is used as a vacuum pumping port and that is sealed after pumping the cavity to high vacuum therethrough. In various embodiments, double-walled Dewar 1 may be implemented in accordance with, or similar to, the hermetically sealed double-walled structures (and vacuum thermal isolation housing) described in U.S. application Ser. No. 12/212,122, filed Sep. 17, 2008, and in U.S. application Ser. No. 12/212,147, filed Sep. 17, 2008, each of which is herein incorporated by reference in its entirety.

FIG. 3 schematically depicts an illustrative cross-sectional view along the longitudinal axis of a superconductor (e.g., HTS) RF head coil array corresponding to embodiments depicted in FIGS. 1A and 1B with the vacuum chamber comprising a Dewar 1 according to various embodiments represented by FIG. 2. As shown, Dewar 1 is sealably joined to a double-walled stainless steel chamber 8 that includes a flange to which cryocooler 7 is sealably mounted. In various embodiments, double-walled stainless steel chamber 8 is hermetically sealed, enclosing an interior chamber (or cavity) 12 in which at least a low vacuum condition and, in accordance with some embodiments, preferably at least a high vacuum condition (e.g., about 10⁻⁶ Torr or lower pressure) is maintained. By way of example, the joint between the hermetically sealed double-walled Dewar 1 (e.g., glass) and the stainless steel chamber may be formed by epoxy bonding, welding, or other hermetically sealed flange connection, providing a sufficient seal to maintain at least a low vacuum condition (e.g., about 10⁻² to about 10⁻⁵ Torr) in the interior chamber portion 6 that houses the superconducting RF coils 3 and thermal conductors 5 (i.e., 5a-5h) and 15. Also by way of example, the vacuum seal between cryocooler 7 and the flange of stainless steel chamber 8 may be provided by an O-ring or other sealing mechanism (e.g., metal gasket/knife-edge connection) to, similarly, maintain the at least low vacuum condition in the interior chamber portion 6 that houses the RF coils 3 and thermal conductors 5 and 15. Those skilled in the art understand, however, that chamber 8 may be made of materials other than stainless steel, e.g., aluminum or other metallic or other non-metallic material, such as glass, ceramic, plastics, or combination of these materials, and such other materials may be appropriately joined to Dewar 1 and cryocooler 7.

In various embodiments, cryocooler 7 may be implemented as any of various single stage or multi-stage cryocoolers, such as, for example, a Gifford McMahon (GM) cryocooler, a pulse tube (PT) cooler, a Joule-Thomson (JT) cooler, a Stirling cooler, or other cryocooler. In various alternative embodiments, the superconductor RF head coil array 10 may be configured for cooling such that coils 3 are cooled by a cryogen, such as liquid helium and liquid nitrogen.

It is understood that while not shown in the drawings, a cryogenically cooled superconductor RF coil array (e.g., array 10) in accordance with various embodiments of the present invention includes at least one electrical feedthrough (e.g., through chamber 8) to provide for coupling electrical signals into and/or out of the array (e.g., for the RF coils, for controlling and/or monitoring any sensors (e.g., pressure and/or temperature, etc.) that may be provided in the module). Additionally, it will be understood that at least a portion of receiver and/or, if applicable, transmitter circuitry (e.g., amplifiers and/or filters and/or appropriate matching and/or decoupling circuitry) for each of the RF coils may be provided within the vacuum chamber; for example, it may be disposed on and in thermal contact with thermal conductors 5a-5h, wherein such cooling may provide for improving noise properties and/or for using superconducting components for at least a portion of such circuitry.

As understood in view of the foregoing description, in accordance with various embodiments of the present invention, superconducting RF head coil array 10 is implemented as a receive-only array, with an RF transmitter being implemented as a separate RF coil (not shown), which in various embodiments may be a conventional (e.g., non-superconducting, such as a conventional copper RF coil) RF transmitter coil or a superconducting RF transmitting coil. Such a separate transmitter coil may be configured external to the vacuum chamber comprising wall(s) 2 (e.g., external to Dewar 1) or, in some embodiments, within the vacuum chamber comprising wall(s) 2 (e.g., within Dewar 1). For instance, in the case that an RF transmission coil is implemented as one or more superconducting RF transmission coils (e.g., a high temperature superconductor (HTS) RF transmitter) that are separate from the RF receiver coils, then, in some embodiments, such one or more superconducting RF transmission coils may be disposed in thermal contact with one or more of thermal conductors 5a-5h.

In some embodiments, superconducting RF head coil array 10 may be implemented as a transmit and receive coil array (a transceiver array), with each of one or more of the superconducting RF coils 3a-3h being used for both transmission and reception of RF signals.

In accordance with various embodiments of the present invention, one or more of the superconducting RF coil elements 3a-3h may be implemented as a multiple resonance RF coil element (e.g., comprising two or more receiving coils having different resonant frequencies, such as for detecting sodium and hydrogen resonances at a given magnetic field (e.g., at 3 Tesla (T)). In some embodiments, two or more different ones of superconducting RF coil elements 3a-3h may be designed to have different resonant frequencies; for example, RF coil elements 3a, 3c, 3e, and 3g may be tuned to a first resonant frequency (e.g., that of hydrogen nuclei at 3 T) and RF coil elements 3b, 3d, 3f, and 3h may be tuned to a second resonant frequency (e.g., that of sodium nuclei at 3 T). As such, a superconducting RF head coil array in accordance with various embodiments of the present invention may be used for acquiring magnetic resonance signals from different types of nuclei in a simultaneous or time-multiplexed manner.

It is further understood that while the hereinabove described figures depict an illustrative embodiment of a superconducting RF head coil array having eight RF receiving channels (e.g., eight receiver coils), alternative embodiments of the present invention may comprise superconducting RF head coil arrays having less or more than eight superconducting RF receiving channels (e.g., less or more than eight RF receiver.

Additionally, as indicated above, it is understood that according to some embodiments of the present invention, a cryogenically-cooled superconducting RF head-coil array coil according to various embodiments of the present invention may be implemented in a magnetic resonance imaging system that employs superconducting gradient coils such as those disclosed in U.S. patent application Ser. No. 12/416,606, filed Apr. 1, 2009, and in Provisional Application No. 61/170,135, filed Apr. 17, 2009, each of which is hereby incorporated by reference in its entirety. In some embodiments, one or more of the superconducting gradient coils may be disposed within the same vacuum chamber as the superconducting RF coils (e.g., the gradient coils may be in thermal contact with the surfaces of thermal conductors 5a-5h that are opposite the surfaces in contact with coils 3a-3h).

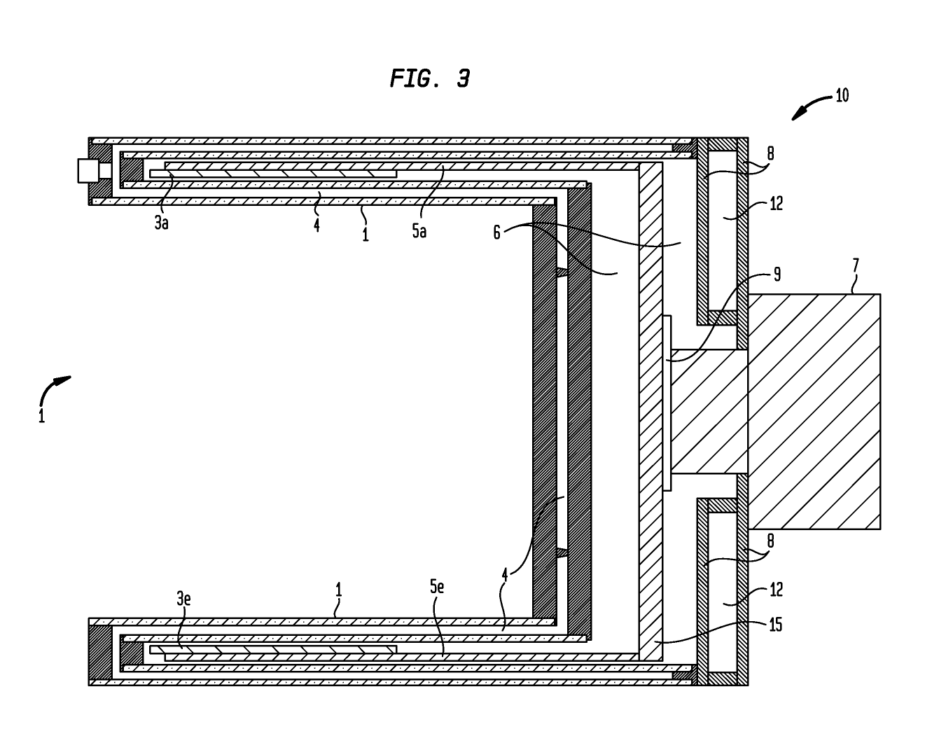

Referring now to FIGS. 4A and 4B, there is shown an illustrative alternative implementation of a superconductor RF head coil array (module), in accordance with some embodiments of the present invention. More specifically, FIG. 4A schematically depicts a cross-sectional view in a plane containing the longitudinal axis, similar to the cross-sectional view depicted with respect to the embodiment of FIG. 3 (e.g., viewing an x-z plane cross-section, using a coordinate system oriented similarly to that for the embodiment of FIGS. 1A, 1B, 2 and 3), while FIG. 4B generally depicts a plan or end-on view, viewed from the left-hand side of FIG. 4A, but showing a cut-away or cross-section of stainless steel chamber 8 to reveal the portion of cryocooler 7 within the chamber 8. As may be appreciated, because the embodiment depicted in FIGS. 4A and 4B is similar to that of FIGS. 1A, 1B, 2 and 3, for convenience and ease of reference, identical reference numerals have been used to identify corresponding or similar elements. As may also be understood, a difference between the embodiment depicted in FIGS. 1B, 2 and 3 and the embodiment depicted in FIGS. 4A and 4B is that the former embodiment is configured such that the end disposed near the cryocooler is closed, whereas the dewar 1 and chamber 8 (sealably connected via, e.g., epoxy bond/sealing 16) of the latter embodiment are configured to provide for the end disposed near the cryocooler being open. Similarly, in connection with the open-ended design of FIGS. 4A and 4B, a thermal conductive ring 25 (cylindrical ring) is thermally coupled to each thermal conductor 5a-h (5a and 5e shown in FIG. 4A) and to cryocooler 7, which is sealably mounted (e.g., via an O-ring sealed flange 19) to chamber 8.

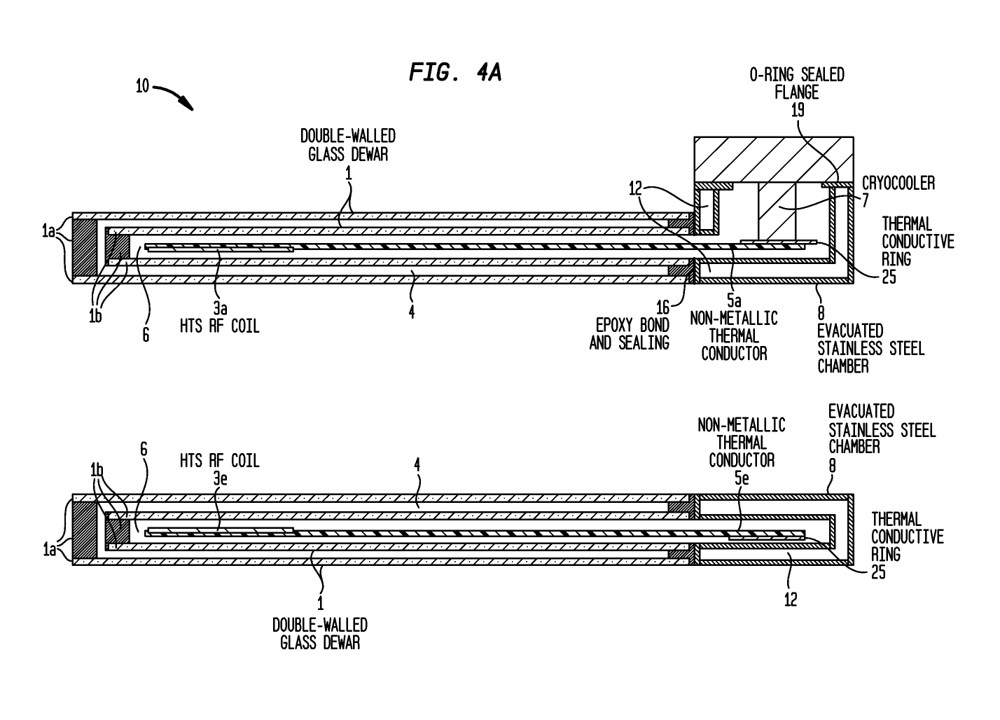

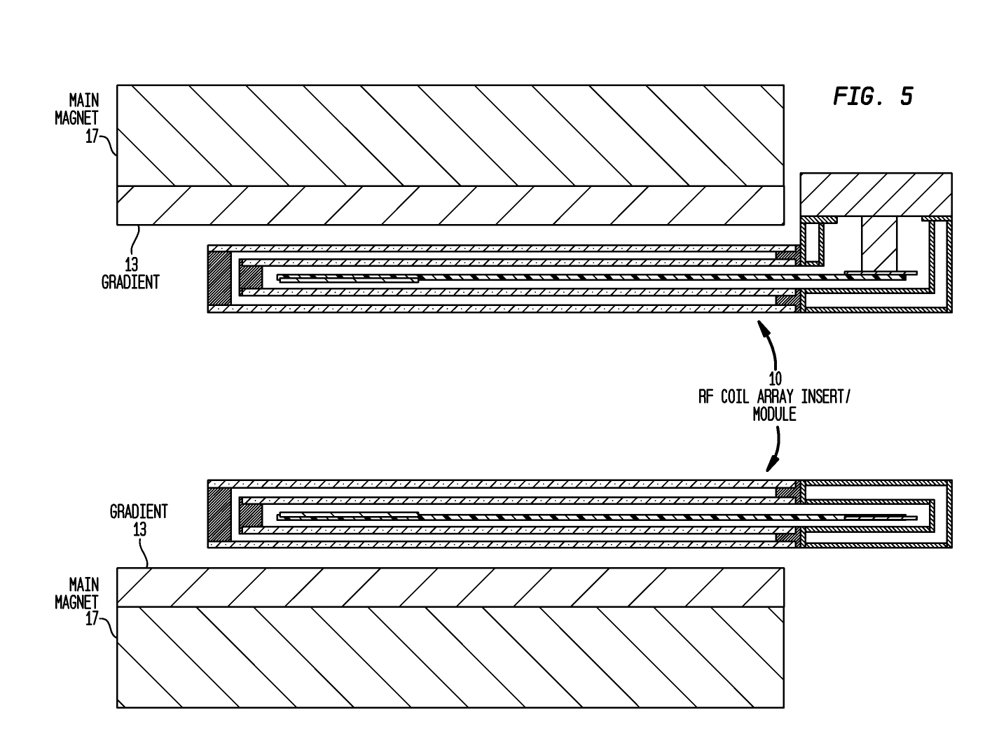

As will be understood by those skilled in the art, a generally cylindrically shaped RF head coil array module such as depicted in the foregoing described embodiments may be well suited for use, for example, in an MRI system that employs a cylindrical, solenoid main magnet structure that generates a substantially uniform, horizontal magnetic field. For example, such an MRI system is schematically depicted in FIG. 5 in longitudinal cross section, and includes cylindrical main magnet 17 having a bore in which a superconductor RF head coil array (module) 10 corresponding to that of FIGS. 4A and 4B is disposed, and which also includes gradient coil(s) 13. It will be understood, however, that cryogenically cooled superconducting RF head coil array 10 may be implemented with main magnet configurations other than a cylindrical, solenoid magnet that provides horizontal fields and/or, for example, may be implemented with open magnet configurations, such as vertical magnet or a double-donut magnet. It is also understood that, according to various embodiments, main magnet 17 may be the main magnet of a whole-body scanner or may be the main magnet of a dedicated (e.g., head-only) system (e.g., such as the main magnet described hereinbelow in connection with FIGS. 7-12).

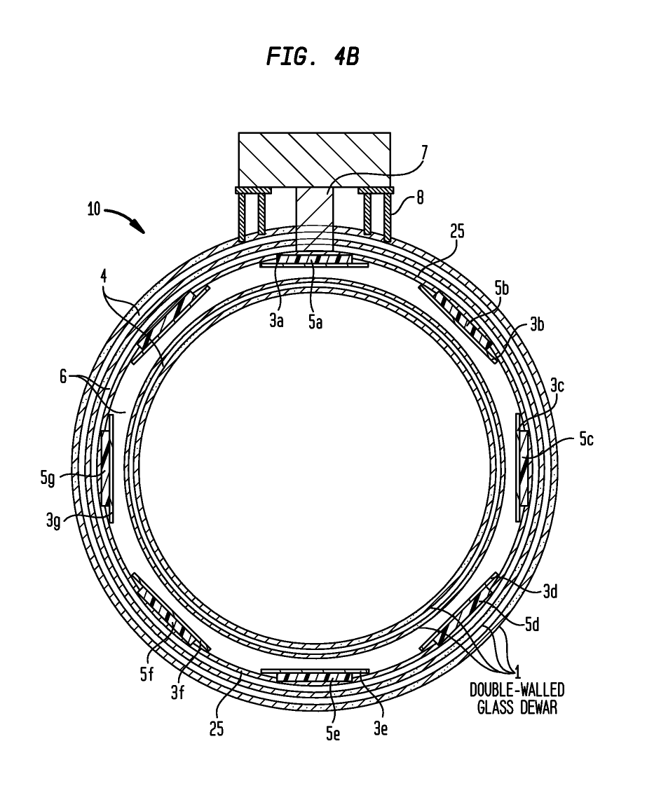

FIG. 6 schematically depicts an illustrative RF head coil array that includes thermal radiation screening, in accordance with some embodiments of the present invention. More specifically, FIG. 6 depicts the upper half of the coil depicted in FIG. 4A, further showing thermal radiation screens 17 that are used as an option to further protect the low temperature of the RF coil 3a and the non-metallic thermal conductor 5a from heating by the radiation from the outer wall of the double-walled glass dewar and the environment outside the dewar. Thermal radiation screen 17 may be made from one or more materials, such as foam, fabricate, cotton, or other non-metallic, good thermal insulation materials or combinations thereof.

As indicated above, while a superconductor RF head coil array in accordance with the hereinabove embodiments may be implemented in connection with a whole-body MRI scanner, such RF head coil arrays may alternatively be used in dedicated, head-only MRI scanners. In accordance with some embodiments of the present invention, a dedicated head-only scanner may implement a superconductor main magnet in accordance with embodiments represented by, and described in connection with, the following drawings. It will be understood, however, that MRI scanners employing a superconductor main magnet according to the ensuing embodiments may employ various RF coil configurations (e.g., array, non-array type, superconducting, non-superconducting, etc.), though some embodiments may employ superconducting RF head coil arrays implemented in accordance with embodiments described hereinabove.

FIG. 7 schematically depicts a cross-sectional view of a superconducting main magnet of a head-only MRI system, the superconducting main magnet comprising double-walled housing 41 and solenoid/helical coils 42, with a subject illustrated disposed therein with the subject's head arranged within the diameter-sensitive volume 43 of the main magnet. As shown, double-walled housing 41 encloses a hermetically sealed region 47 that is under at least a low vacuum condition, but preferably is under high vacuum (e.g., 10⁻⁶ to 10⁻¹² Torr), and also encloses an interior chamber region 45 in which superconducting coils 42 are disposed and which is under at least a low vacuum condition (e.g., 10⁻³ to 10⁻⁶ Torr).

More specifically, in accordance with some embodiments, the superconducting main magnet is an electromagnet system comprising a vacuum thermal isolation housing 41 (e.g., a dewar) that is integrated with a cryogenic system (not shown) to provide for cooling superconducting coils 42 via a heat pipe (not shown) and a heat sink assembly (not shown) in thermal contact with the superconducting coils. Superconducting coils may be implemented as high temperature superconductor (HTS) coils and, in some embodiments, may comprise at least one of the following superconductor materials: YBaCuO, BiSrCaCuO, TIBiCaCuO, and MgB₂. By way of example, the temperature in the interior chamber region in which the coils are disposed may be in the range of about 77 K-80 K.

In accordance with some embodiments, as shown, the coils are configured as (i) a first coil set that is disposed in a first region to cover or surround or otherwise be disposed adjacent to an individual's head, and (ii) a second coil set that is coaxial with the first coil set and is disposed in a second region to cover or surround or otherwise be disposed adjacent to the individuals shoulders or upper torso, wherein the inner radius of the first set of coils is less than the inner radius of the second set of coils, and the coils are configured to provide a uniform magnetic field in the region of the individual's head. As will be understood by those skilled in the art in view of the herein disclosure, various embodiments may vary the number of coils per set, the coil radii, number of turns, longitudinal position and length, and electric current magnitude and direction in each coil to provide a desired magnetic field distribution. In accordance with some embodiments of the present invention, the longitudinal position and extension, the number of turns, and electric current direction of each coil are designed to provide 1-10 ppm uniform magnetic field within the first region for head imaging.

By way of example, the first set of coils may include at least two coils having an inner radius in a range of about 25-35 cm and disposed in a first region of a length along the common axis in a range of 40-60 cm to cover a head and neck of a human body, and the second set of coils may include at least one coil having an inner radius in a range of about 30-40 cm and disposed in a second region of a length along the common axis in a range of 15-25 cm to cover a portion of a human torso. In various alternative embodiments, the length of the first and second regions may, for example, range from about 20-70 cm and 10-40 cm, respectively, and the inner radii of the first and second set of coils may range from about 10-40 com and 20-50 cm, respectively. Some embodiments, may employ a length of the first and second regions in a range from about 10-20 cm and 20-30 cm respectively. Additionally, some embodiments may employ an inner radius of the first and second coils of about 10-20 cm and 20-30 cm, respectively.

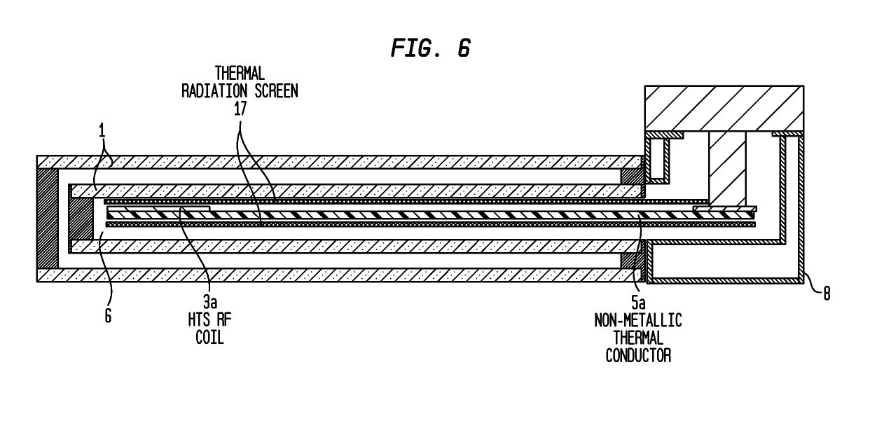

By way of illustrative example, FIG. 8 depicts with reference to the z-r plane, with dimensions in meters (m), the longitudinal extent L2 of a first set of coils (e.g., corresponding to the four leftmost coil sets depicted in FIG. 7) having an inner radius of 0.28 meters, the longitudinal extent L1 of a second coil set (e.g., corresponding to the rightmost coil set in FIG. 7) having an inner radius of 0.38 meters, and DSV 43 having a radius that is about 0.1 meters and offset by about 0.05 meters from the transition from the first to second set of coils (from L2 to L1) along the z-axis, in accordance with an illustrative example according to some embodiments of the present invention.

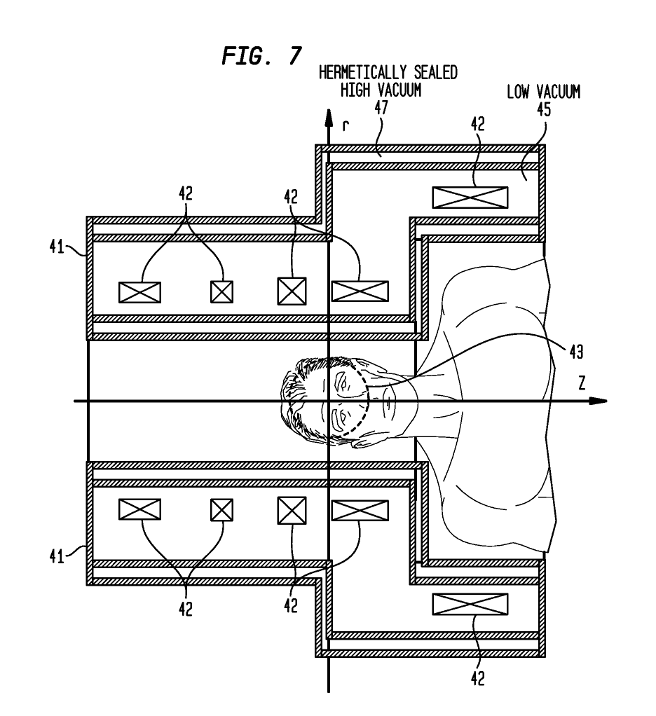

FIG. 9 depicts a normalized current distribution for the main magnet coil arrangement corresponding to the illustrative embodiment of FIGS. 7 and 8. As shown, in accordance with some embodiments, at least one coil is wound to carry current in the reverse direction relative to other coils.

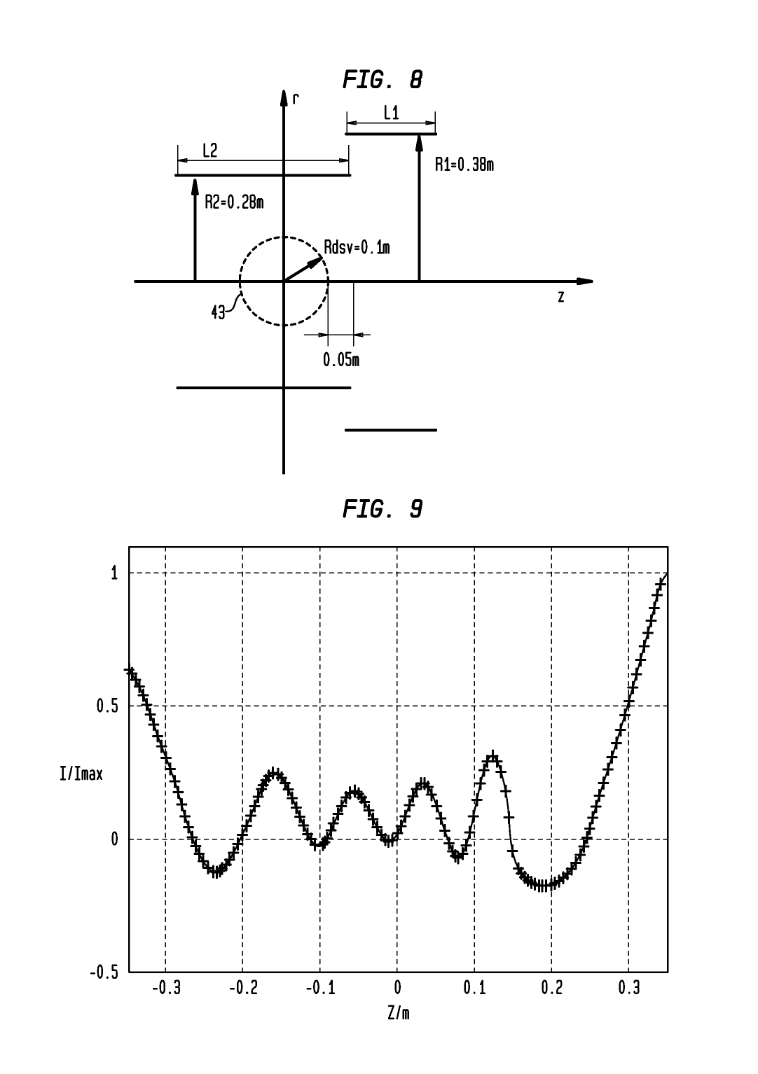

FIG. 10 is an illustrative coil pattern (depicted in the z-r plane, with units normalized to meters) of a 3 T head magnetic resonance imaging scanner, in accordance with various embodiments of the present invention. More specifically, active shield coil 51 is disposed at the outer side, main magnet coils 52 comprise eight coil sets, and a diameter-sensitive volume (DSV) 53 of homogeneous fields is about 200 mm in diameter (i.e., a radius of about 0.1 meter). The shield coil 51 may have a radius, for example, in the range of about 60-70 cm, though other radii are possible depending on the particular implementation. By way of illustrative, non-limiting example, the following table provides dimensions and current direction for coils arranged according to the embodiment of FIG. 10, wherein the first set of coils comprise coil numbers 1 through 6, the second set of coils comprise coil numbers 7 and 8, the shielding coil is identified as coil 9, R1 is the inner radius, R2 is the outer radius, Z1 is the first longitudinal position, Z2 is the second longitudinal position, and the current direction J is identified as positive (+) or negative (−):

| Coil no. | R₁ (m) | R₂(m) | Z₁(m) | Z₂(m) | J |
|---|---|---|---|---|---|
| 1 | 0.2501 | 0.3028 | −0.4132 | −0.2897 | + |
| 2 | 0.2702 | 0.2916 | −0.2519 | −0.2325 | + |
| 3 | 0.2592 | 0.3033 | −0.1873 | −0.1327 | + |
| 4 | 0.2569 | 0.3032 | −0.0765 | −0.0349 | + |
| 5 | 0.2573 | 0.3027 | 0.0213 | 0.0606 | + |
| 6 | 0.2669 | 0.3012 | 0.1157 | 0.1680 | + |
| 7 | 0.3561 | 0.3821 | 0.1822 | 0.1980 | − |
| 8 | 0.3329 | 0.3929 | 0.2610 | 0.4433 | + |
| 9 | 0.6608 | 0.6615 | −0.450 | 0.450 | + |

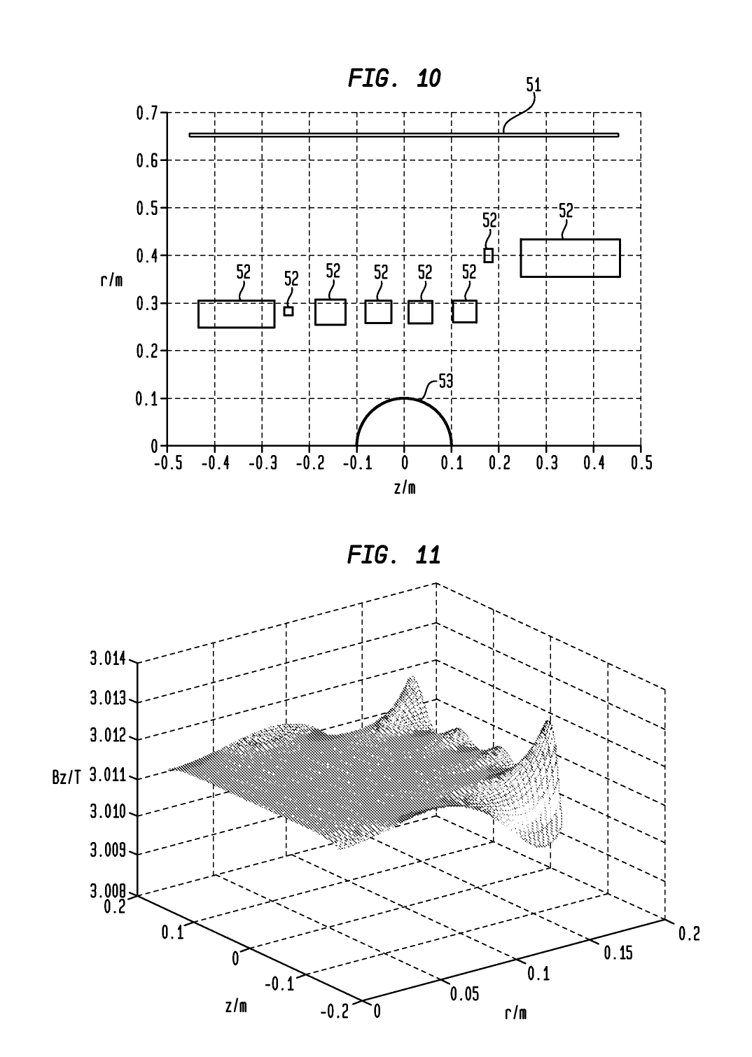

FIG. 11 is a plot showing the magnetic field distribution for the illustrative embodiment depicted in FIG. 10, with illustrative dimensions and current directions as per the foregoing table. As shown, a 3 T homogeneous field provides a 200 mm DSV.

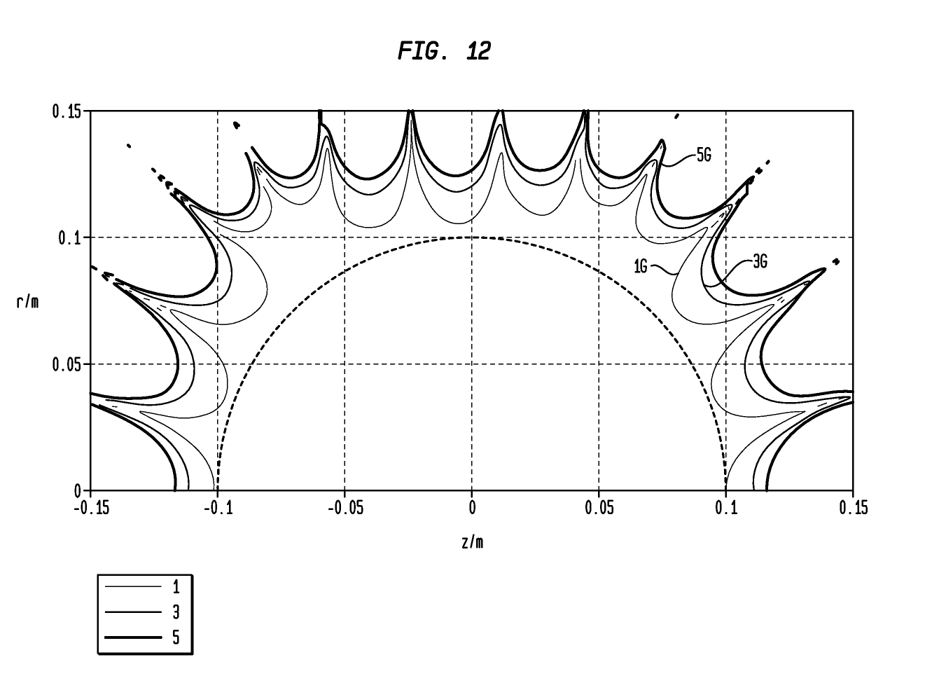

FIG. 12 shows the fringe fields of one Gauss, three Gauss and five Gauss lines for the field distribution of FIG. 11, in accordance with an illustrative embodiment of the present invention.

Accordingly, as may be appreciated, FIG. 10 illustrates a non-limiting example of an embodiment according to the present invention. In this example, as described, the outer layer is an active shield coil 51, and the depicted inner layer comprises main magnet coils 52 having eight coil sets providing an asymmetric structure, with the coils on the right hand side (towards increasing z) having a bigger diameter for accommodating a patient's shoulders. In this illustrative and non-limiting embodiment, total length of the magnet is 0.86 m, the peak magnetic field is 5.04 Tesla at a current density J=1.2×10⁸ A/m², and the DSV 53 is 200 mm in diameter.

According to these parameters, FIG. 11 plots the field distribution in cylinder of z=−0.1□+−0.1 m, r=0.2 m. In cylinder of z=−0.1□+−0.1 m, r=0.15 m, the fringe fields of one Gauss, three Gauss and five Gauss lines is drawn in FIG. 12, and the 200 mm DSV is inside one Gauss line as expected and desired.

Accordingly, it may also be understood in view of the foregoing that for a head-only magnetic resonance imaging scanner according to embodiments of the present invention, the bore surrounding a DSV 43 of homogeneous fields is preferably not much larger in diameter than what is necessary to fit a patient's head, while the main magnet bore also includes a portion designed with a diameter having an appropriate size to accommodate the shoulder as shown in FIG. 7. By contrast with a whole-body MRI, a head-only main magnet in accordance with some embodiments of the present invention has a smaller DSV, so the size of superconducting magnet can be reduced, and a smaller Dewar and magnet system can be achieved, and the costs can be thus also be reduced.

The present invention has been illustrated and described with respect to specific embodiments thereof, which embodiments are merely illustrative of the principles of the invention and are not intended to be exclusive or otherwise limiting embodiments. Accordingly, although the above description of illustrative embodiments of the present invention, as well as various illustrative modifications and features thereof, provides many specificities, these enabling details should not be construed as limiting the scope of the invention, and it will be readily understood by those persons skilled in the art that the present invention is susceptible to many modifications, adaptations, variations, omissions, additions, and equivalent implementations without departing from this scope and without diminishing its attendant advantages. For instance, except to the extent necessary or inherent in the processes themselves, no particular order to steps or stages of methods or processes described in this disclosure, including the figures, is implied. In many cases the order of process steps may be varied, and various illustrative steps may be combined, altered, or omitted, without changing the purpose, effect or import of the methods described. It is further noted that the terms and expressions have been used as terms of description and not terms of limitation. There is no intention to use the terms or expressions to exclude any equivalents of features shown and described or portions thereof. Additionally, the present invention may be practiced without necessarily providing one or more of the advantages described herein or otherwise understood in view of the disclosure and/or that may be realized in some embodiments thereof. It is therefore intended that the present invention is not limited to the disclosed embodiments but should be defined in accordance with the claims that follow.

What is claimed is:

1. A system for head magnetic resonance imaging, comprising:
a first and second set of high temperature superconductor coils which are configured to be coaxial relative to a common longitudinal axis;
wherein the first coil set includes at least two coils having an inner radius and disposed in a first region of a length along the common axis to cover a head and neck of a human body, and the second coil set includes at least one coil having an inner radius and disposed in a second region of a length along the common axis to cover a portion of a human torso, wherein the inner radius of the second coil set is greater than the inner radius of the first coil set; and
wherein the first and second coils are configured to provide a uniform magnetic field in the first region to provide for imaging a region of interest of the individual's head when positioned within the first region.

2. The system of claim 1, wherein the longitudinal position and extension, the number of turns, and electric current direction of each coil are designed to provide a 1-10 ppm uniform magnetic field within the first region for head imaging.

3. The system of claim 1, wherein the first set of coils includes at least two coils having an inner radius in a range of 25-35 cm and disposed in a first region of a length along the common axis in a range of 40-60 cm, and the second set of coils includes at least one coil having an inner radius in a range of 30-40 cm and disposed in a second region of a length along the common axis in a range of 15-25 cm to cover a portion of a human torso.

4. The system of claim 1, wherein the portion of human torso comprises the shoulders.

5. The system of claim 1 further comprising a vacuum thermal isolation housing comprising a double wall hermetically sealed high vacuum jacket at a pressure of about 10⁻⁶ to 10⁻¹² Torr, which encloses a low vacuum space at a pressure between 10⁻³ to 10⁻⁶ Torr, wherein the high temperature superconductor coils are disposed in said low vacuum space.

6. The system of claim 5, wherein the temperature in the low vacuum space is in the range of about 77K-80K.

7. The system of claim 1, wherein the high temperature superconductor coil comprises at least one superconductor material selected from the group consisting of YBaCuO, BiSrCaCuO, TlBiCaCuO, and MgB₂.

8. The system of claim 1, wherein at least one coil which are wound to carry current in the reverse direction relative to the rest of coils.

9. The system of claim 1, further comprising a shielding coil which surrounds said common longitudinal axis and is coaxial with said first and second coils.

10. The system of claim 9, wherein the shielding coil extends over the length of the first and second regions.

11. The system of claim 9, wherein the shielding coil has a radius in a range of 60-70 cm.

12. The system of claim 1, wherein the strength of the magnetic field is in the range of about 3.0-5.0 T.

13. The system of claim 1, wherein the length of the first and second region is 10-20 cm and 20-30 respectively.

14. The system of claim 1, wherein the inner radius of the first and second set of coils is 10-20 cm and 20-30 respectively.

15. The system of claim 1, further comprising a shielding coil, wherein the first coil set comprises six coils, the second coil set comprises two coils, and the dimensions and current direction for the first, second, and shielding coils are as follows:

| Coil no. | R₁ (m) | R₂(m) | Z₁(m) | Z₂(m) | J |
|---|---|---|---|---|---|
| 1 | 0.2501 | 0.3028 | −0.4132 | −0.2897 | + |
| 2 | 0.2702 | 0.2916 | −0.2519 | −0.2325 | + |
| 3 | 0.2592 | 0.3033 | −0.1873 | −0.1327 | + |
| 4 | 0.2569 | 0.3032 | −0.0765 | −0.0349 | + |
| 5 | 0.2573 | 0.3027 | 0.0213 | 0.0606 | + |
| 6 | 0.2669 | 0.3012 | 0.1157 | 0.1680 | + |
| 7 | 0.3561 | 0.3821 | 0.1822 | 0.1980 | − |
| 8 | 0.3329 | 0.3929 | 0.2610 | 0.4433 | + |
| 9 | 0.6608 | 0.6615 | −0.450 | 0.450 | + |

wherein, the first set of coils are identified as coil nos. 1 through 6, the second set of coils are identified as coil no. 7 and 8, the shielding coil is identified as coil 9, R1 represents the inner radius, R2 represents the outer radius, Z1 represents the first longitudinal position, Z2 represents the second longitudinal position, and J identifies the current direction as positive (+) or negative (−).

16. The system according to claim 1, further comprising a superconductor radiofrequency head coil array module disposed coaxially with respect to said common longitudinal axis and configured to at least receive radiofrequency signals generated within said first region in which the individual's head is positioned for imaging.

17. The system according to claim 16, wherein the head coil array comprises a plurality of high temperature superconductor coils disposed azimuthally about said common longitudinal axis.
